(19) United States
(12) Patent Application Publication
(10) Pub. No.: US 2007/0064953 A1
(43) Pub. Date: Mar. 22, 2007

(54) SPEAKER PROTECTION CIRCUIT

(75) Inventors: Takuma ISHIDA, Kadoma-shi, Osaka (JP); Makoto YAMAMOTO, Kadoma-shi, Osaka (JP)

Correspondence Address: HAMRE, SCHUMANN, MUELLER & LARSON P.C., P.O. BOX 2902-0902, MINNEAPOLIS, MN, 55402, US

(73) Assignee: MATSUSHITA ELECTRIC INDUSTRIAL CO., LTD., Osaka (JP)

(21) Appl. No.: 11/533,540

(22) Filed: Sep. 20, 2006

(30) Foreign Application Priority Data
Sep. 22, 2005 (JP) JP2005-276386

(51) Int. Cl. H03G 11/00

(52) U.S. Cl. 381/55; 381/189

(57) ABSTRACT

This speaker protection circuit includes: a voltage comparator that compares a voltage of a reference bias terminal of an amplifying circuit constituting a BTL amplifying device with a preset threshold voltage; and first and second switches for switching between a mode of supplying an electric current to each of two power amplifying circuits and a mode of cutting off the electric current. When the voltage of the reference bias terminal is lower than the threshold voltage, based on an output level of the voltage comparator, at least one of the first and second switches is turned off to cut off a current supply to each of the power amplifying circuits so that driving of a speaker by the power amplifying circuits is halted. Thus, it is possible to suppress, using a relatively simple configuration, an offset current generated in a speaker due to an abnormality of the voltage of a reference bias terminal.

### BACKGROUND OF THE INVENTION

1. Field of the Invention

The present invention relates to a circuit in an amplifying device of a BTL (Balanced Trans Less) configuration, which is provided to protect a speaker driven by the amplifying device.

2. Description of Related Art

An amplifying device of the BTL configuration is known as an amplifying device for driving a load such as a speaker or the like. In an amplifying device of the BTL configuration (hereinafter, referred to as a BTL amplifying device), two amplifiers are used, and a signal in phase with an input signal is inputted to one of the amplifiers, while a signal obtained by inversion of the input signal is inputted to the other. According to this configuration, the BTL amplifying device can achieve a twofold increase in output voltage, namely, a fourfold increase in power. This allows the BTL amplifying device to drive a load such as a speaker or the like directly without using a transformer and thus provide excellent frequency and distortion characteristics. Further, compared with an amplifying device of a configuration other than the BTL configuration, the BTL amplifying device has excellent features such as allowing a large output to be obtained using the same power supply voltage. Such BTL amplifying devices have been used widely as components aboard audio equipment and the like.

A BTL amplifying device, however, has a disadvantage that when a coupling capacitor for signal input is deteriorated and leakage occurs, a DC offset signal is generated from the BTL amplifying device, so that an offset current flows through a speaker. An excessively large offset current may cause a breakdown of the speaker. With respect to this problem, for example, Patent Document 1 (JP 2000-174571 A) discloses a BTL amplifying device of a configuration in which driving of a speaker is halted upon detection of an offset current as described above.

Furthermore, in a conventional BTL amplifying device, in order to secure a large maximum output power, as a power supply for a power amplifying circuit of the BTL configuration that directly drives a speaker, a power supply at a voltage higher than that of a power supply for a circuit provided in a preceding stage is provided separately. Moreover, in the case where a reference bias for the power amplifying circuit is set separately from a reference bias for a circuit provided in a stage preceding the power amplifying circuit so that a maximum output dynamic range is obtained, two or more reference biases are required. FIG. 12 shows an example of a configuration of such a conventional BTL amplifying device.

In FIG. 12, an input signal to be inputted to an input terminal 104 is supplied to a non-inverting amplifying circuit 109 via a coupling capacitor 101. Further, an output voltage VREF 11 of a bias circuit 107 is used as a reference voltage for the non-inverting amplifying circuit 109. An output of the non-inverting amplifying circuit 109 is inputted to each of a non-inverting amplifying circuit 111 and an inverting amplifying circuit 112 that are set so as to be equal in amplification factor. Outputs of the non-inverting amplifying circuit 111 and the inverting amplifying circuit 112 are inputted to level shifting circuits 113 and 114, respectively, in each of which a level shift is performed so that a signal whose operating point is at a reference voltage VREF 31 is obtained.

Outputs of the level shifting circuits 113 and 114 are inputted to power amplifying circuits 115 and 116, respectively. Reference potentials for the power amplifying circuits 115 and 116 are set to values of the output voltage VREF 11 of the bias circuit 107, an output voltage VREF 21 of a bias circuit 108, and the reference voltage VREF 31 produced by a level shifting circuit 110. Further, the power amplifying circuits 115 and 116 are set so as to have an equal amplification factor.

A speaker 121 is connected between an output terminal B11 of the power amplifying circuit 115 and an output terminal B21 of the power amplifying circuit 116. Further, a capacitor 102 connected between a reference bias terminal 105 and a ground has a function of smoothing the output voltage VREF 11. Further, a capacitor 103 connected between a reference bias terminal 106 and the ground has a function of smoothing the output voltage VREF 21. Further, a power supply terminal 117 of the power amplifying circuits 115 and 116 is connected to a power supply 119. Further, a ground terminal 118 of the power amplifying circuits 115 and 116 is connected to a ground potential.

In the above-described configuration, from the non-inverting amplifying circuit 111 and the inverting amplifying circuit 112, signals whose phases are inverted from each other are supplied to the power amplifying circuits 115 and 116, respectively. That is, when an output current with an amplified power from the power amplifying circuit 115 is supplied to the speaker 121, the power amplifying circuit 116 operates to lead the current from the speaker 121 thereinto. Conversely, when an output current with an amplified power from the power amplifying circuit 116 is supplied to the speaker 121, the power amplifying circuit 115 operates to lead the current from the speaker 121 thereinto.

In the above-described BTL amplifying device, in the event of an abnormality in which leakage occurs in the capacitor 102 connected to the bias circuit 107 or the reference bias terminal 105 and a power supply line or a ground line are short-circuited, a DC offset signal is generated from the BTL amplifying device, so that an offset current flows though the speaker 121. In this case, if an excessively large offset current reaches the speaker 121, the speaker 121 may be damaged.

### SUMMARY OF THE INVENTION

With the foregoing in mind, it is an object of the present invention to suppress, using a relatively simple configuration, an offset current generated in a speaker due to an abnormality of the voltage of a reference bias terminal.

In order to solve the above-described problem, a speaker protection circuit of a first configuration according to the present invention is a speaker protection circuit for use in a BTL amplifying device that drives a speaker using two power amplifying circuits to which two signals whose phases are inverted from each other are inputted, respectively. The speaker protection circuit includes: a first voltage comparator that compares a voltage of a reference bias terminal of an amplifying circuit constituting the BTL amplifying device with a preset threshold voltage; and a switch for switching between a mode of supplying an electric current to each of the two power amplifying circuits and a mode of cutting off the electric current. In the speaker protection circuit, when the voltage of the reference bias terminal is lower than the threshold voltage, based on an output level of the first voltage comparator, the switch is turned off to cut off a current supply to each of the power amplifying circuits so that driving of the speaker by the power amplifying circuits is halted.

A speaker protection circuit of a second configuration according to the present invention is a speaker protection circuit for use in a BTL amplifying device that drives a speaker using two power amplifying circuits to which two signals whose phases are inverted from each other are inputted, respectively. The speaker protection circuit includes: a first voltage comparator that compares a voltage of a reference bias terminal of an amplifying circuit constituting the BTL amplifying device with a preset threshold voltage; and a switch that is interposed between the speaker and respective outputs of the two power amplifying circuits. In the speaker protection circuit, when the voltage of the reference bias terminal is lower than the threshold voltage, based on an output level of the first voltage comparator, the switch is turned off to cut off a driving current from each of the power amplifying circuits to the speaker so that driving of the speaker is halted.

A speaker protection circuit of a third configuration according to the present invention is a speaker protection circuit for use in a BTL amplifying device that drives a speaker using two power amplifying circuits to which two signals whose phases are inverted from each other are inputted, respectively. In the speaker protection circuit, each of the two power amplifying circuits includes: a muting circuit that halts an amplifying operation of the each of the two power amplifying circuits; and a mute terminal for allowing the muting circuit to operate. The speaker protection circuit includes a first voltage comparator that compares a voltage of a reference bias terminal of an amplifying circuit constituting the BTL amplifying device with a preset threshold voltage. In the speaker protection circuit, an output of the first voltage comparator is connected to the mute terminal, and when the voltage of the reference bias terminal is lower than the threshold voltage, based on an output level of the first voltage comparator, the amplifying operation of at least one of the two power amplifying circuits is halted by the corresponding muting circuit so that driving of the speaker is halted.

### BRIEF DESCRIPTION OF THE DRAWINGS

FIG. 1 is a circuit diagram of a BTL amplifying device including a speaker protection circuit according to a first embodiment.

FIG. 2 is a circuit diagram of a BTL amplifying device including a speaker protection circuit according to a second embodiment.

FIG. 3 is a circuit diagram of a BTL amplifying device including a speaker protection circuit according to a third embodiment.

FIG. 4A is a diagram showing a specific example of a circuit configuration of a window comparator in the circuit diagram shown in FIG. 3.

FIG. 4B is a diagram showing a specific example of a circuit configuration of a window comparator in the circuit diagram shown in FIG. 3.

FIG. 5 is a circuit diagram of a BTL amplifying device including a speaker protection circuit according to a fourth embodiment.

FIG. 6 is a circuit diagram of a BTL amplifying device including a speaker protection circuit according to a fifth embodiment.

FIG. 7 is a circuit diagram of a BTL amplifying device including a speaker protection circuit according to a sixth embodiment.

FIG. 8 is a circuit diagram of a BTL amplifying device including a speaker protection circuit according to a seventh embodiment.

FIG. 9 is a circuit diagram of a BTL amplifying device including a speaker protection circuit according to an eighth embodiment.

FIG. 10 is a circuit diagram of a BTL amplifying device including a speaker protection circuit according to a ninth embodiment.

FIG. 11 is a circuit diagram of a BTL amplifying device including a speaker protection circuit according to the tenth embodiment.

FIG. 12 is a circuit diagram showing a configuration of a conventional BTL amplifying device.

### DETAILED DESCRIPTION OF THE INVENTION

The speaker protection circuit of the first configuration according to the present invention may have the following configuration. That is, the speaker protection circuit further includes a second voltage comparator that compares the voltage of the reference bias terminal with a second threshold voltage higher than the threshold voltage. When the voltage of the reference bias terminal is higher than the second threshold voltage, based on an output level of the second voltage comparator, the switch is turned off to cut off the current supply to each of the power amplifying circuits so that the driving of the speaker by the power amplifying circuits is halted.

Furthermore, the speaker protection circuit may have a configuration in which the driving current from each of the power amplifying circuits to the speaker is cut off so that the driving of the speaker is halted.

Furthermore, the speaker protection circuit may have a configuration in which the amplifying operation of at least one of the two power amplifying circuits is halted by the muting circuit so that the driving of the speaker is halted.

According to these configurations, not only when a voltage of a reference bias terminal drops abnormally but also when it rises abnormally, driving of a speaker can be halted immediately. An abnormal rise in voltage may result from, for example, a short circuit between a reference bias terminal and a power supply line. Even in such a case, the flow of an offset current through a speaker is suppressed, which can avoid the possibility that the speaker is damaged by an excessively large offset current.

The speaker protection circuit of the second configuration according to the present invention may have the following configuration. That is, the speaker protection circuit further includes: a low-pass filter that smooths a signal inputted from an input terminal and outputs a DC voltage; a third voltage comparator that compares an output voltage of the low-pass filter with a third threshold voltage; and a fourth voltage comparator that compares the output voltage of the low-pass filter with a fourth threshold voltage higher than the third threshold voltage. When the output voltage of the low-pass filter is lower than the third threshold voltage or higher than the fourth threshold voltage, the switch is turned off to cut off the current supply to each of the power amplifying circuits so that the driving of the speaker by the power amplifying circuits is halted.

Furthermore, the speaker protection circuit may have a configuration in which the driving current from each of the power amplifying circuits to the speaker is cut off so that the driving of the speaker is halted.

Furthermore, the speaker protection circuit may have a configuration in which the amplifying operation of at least one of the two power amplifying circuits is halted by the muting circuit so that the driving of the speaker is halted.

According to these configurations, not only when an abnormality of the voltage of a reference bias terminal occurs but also when a DC component of a voltage signal of an input terminal drops or rises abnormally, driving of a speaker can be halted immediately. As a result, the flow of an offset current through the speaker is suppressed, which can avoid the possibility that the speaker is damaged by an excessively large offset current.

In the speaker protection circuit of the third configuration according to the present invention, a register that operates on a predetermined reference clock is provided within an output circuit of the first voltage comparator. In the speaker protection circuit, an output voltage of the first voltage comparator is stored once in the register according to the reference clock and then is outputted from the register so that a change in the output voltage of the voltage comparator that occurs in a time period shorter than a cycle of the reference clock is not transmitted to a succeeding stage.

According to this configuration, in addition to the effects of the above-described configurations, there can be provided an effect that a malfunction due to a change in level that occurs in a very short time such as noise is prevented, and thus improved reliability is obtained. This effect is attributable to the fact that even when the output voltage of a voltage comparator changes in a time period shorter than a cycle of a reference clock under an influence of chattering, noise or the like, such a change is not transmitted to an output of a register circuit.

According to the speaker protection circuit of the present invention, in the case where a voltage of a reference bias terminal drops abnormally due to, for example, leakage in an electronic component connected to a reference bias terminal and a short circuit between the reference bias terminal and a ground line, driving of a speaker is halted immediately. As a result, the flow of an offset current through the speaker is suppressed, which can avoid the possibility that the speaker is damaged by an excessively large offset current.

### First Embodiment

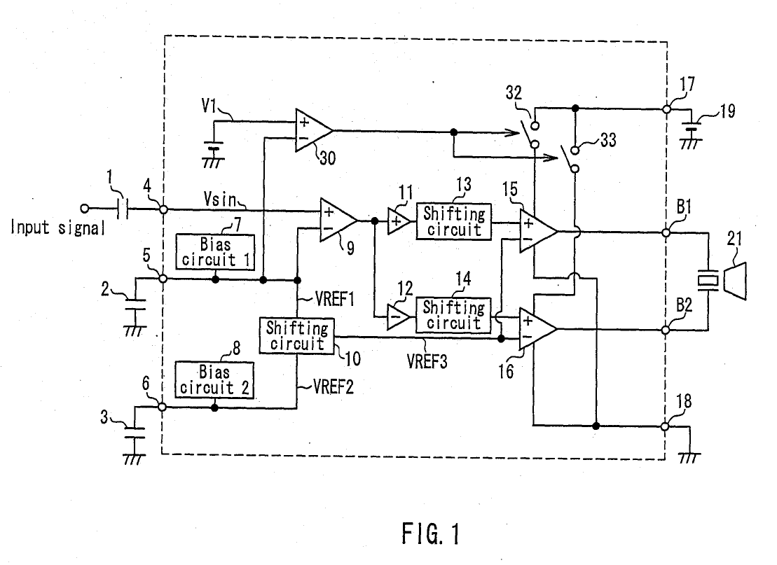

FIG. 1 is a circuit diagram of a BTL amplifying device including a speaker protection circuit according to a first embodiment of the present invention. In FIG. 1, an input signal is inputted to an input terminal 4 via a coupling capacitor 1. A signal Vsin inputted to the input terminal 4 is supplied to a first non-inverting amplifying circuit 9 as an input signal. A capacitor 2 is connected to a first reference bias terminal 5 connected to the other input terminal of the first non-inverting amplifying circuit 9. Further, a capacitor 3 is connected to a second reference bias terminal 6. A first bias circuit 7 outputs a first reference voltage (namely, a voltage of the first reference bias terminal 5) VREF1. Further, a second bias circuit 8 outputs a second reference voltage VREF2. The first non-inverting amplifying circuit 9 uses VREF1 as a reference potential. A first level shifting circuit 10 generates a third reference voltage VREF3 based on the first reference voltage VREF 1 and the second reference voltage VREF2.

Moreover, a second non-inverting amplifying circuit 11 applies non-inverting amplification to an output signal of the first non-inverting amplifying circuit 9. Further, an inverting amplifying circuit 12 applies inverting amplification to an output signal of the first non-inverting amplifying circuit 9. The second non-inverting amplifying circuit 11 and the inverting amplifying circuit 12 are set so as to have the same value for an amplification factor. A second level shifting circuit 13 performs a level shift so that an operating point of an output signal of the second non-inverting amplifying circuit 11 is at the third reference voltage VREF3. Further, a third level shifting circuit 14 performs a level shift so that an operating point of a signal supplied from the inverting amplifying circuit 12 is at the third reference voltage VREF3. An output signal of the second level shifting circuit 13 is inputted to a first power amplifying circuit 15. Further, an output signal of the third level shifting circuit 14 is inputted to a second power amplifying circuit 16.

The first power amplifying circuit 15 and the second power amplifying circuit 16 apply power amplification to the output signal of the second level shifting circuit 13 and the output signal of the third level shifting circuit 14, respectively. The first power amplifying circuit 15 and the second power amplification circuit 16 are set so as to be equal in amplification factor. A power supply 19 is connected between a ground terminal and a power supply terminal 17 for supplying power to the first power amplifying circuit 15 and the second power amplifying circuit 16. A speaker 21 is connected between an output terminal B1 of the first power amplifying circuit 15 and an output terminal B2 of the second power amplifying circuit 16.

Furthermore, a voltage comparator 30 compares the first reference voltage VREF1 with a preset threshold voltage V1. An output of the voltage comparator 30 is used as an ON/OFF control signal for a first switching element 32 and a second switching element 33. The first switching element 32 is connected between a power supply line of the first power amplifying circuit 15 and the power supply terminal 17. The second switching element 33 is connected between a power supply line of the second power amplifying circuit 16 and the power supply terminal 17.

The following describes operations of a BTL amplifying device and a speaker protection circuit.

Via the coupling capacitor 1, an input signal is inputted to the non-inverting amplifying circuit 9 that uses the output voltage VREF1 of the bias circuit 7 as a reference potential. An output of the non-inverting amplifying circuit 9 is inputted to each of the non-inverting amplifying circuit 11 and the inverting amplifying circuit 12 that are set so as to be equal in amplification factor. Outputs of the non-inverting amplifying circuit 11 and the inverting amplifying circuit 12 are inputted to the level shifting circuits 13 and 14, respectively, in each of which a level shift is performed so that a signal is obtained whose operating point is at the reference voltage VREF 3.

Outputs of the level shifting circuits 13 and 14 are inputted to the power amplifying circuits 15 and 16, respectively. Reference potentials for the power amplifying circuits 15 and 16 are set to a value of the reference voltage VREF3 generated by the level shifting circuit 10. Further, the power amplifying circuits 15 and 16 are set so as to have the same value of the amplification factor. That is, two signals whose phases are inverted from each other are inputted to the two power amplifying circuits 15 and 16 that are equal in amplification factor.

Output signals of the power amplification circuits 15 and 16 are inputted to the speaker 21 and outputted as audio.

A speaker protection circuit in the above-described BTL amplifying device is composed of the voltage comparator 30, the first switching element 32, the second switching element 33 and the like. The voltage comparator 30 compares the reference voltage VREF1 with the threshold voltage V1. In the case where the reference voltage VREF 1 is not lower than the threshold voltage V1, the voltage comparator 30 outputs a high level voltage. As a result, the switching elements 32 and 33 are turned on, and thus the power amplifying circuits 15 and 16 are supplied with a power supply voltage to be brought into an operating state. Conversely, in the case where the reference voltage VREF 1 is lower than the threshold voltage V1, the voltage comparator 30 outputs a low level voltage, so that the switching elements 32 and 33 are turned off. As a result, power supply paths to the power amplifying circuits 15 and 16 are cut off, thus bringing operations to a halt.

Furthermore, the power amplifying circuits 15 and 16, which operate in the case where the reference voltage VREF1 is not lower than the threshold voltage V1, drive the speaker upon receipt of signals whose phases are inverted from each other respectively from the non-inverting amplifying circuit 11 and the inverting amplifying circuit 12. In the case where the reference voltage VREF1 is lower than the threshold voltage V1, the power amplification circuits 15 and 16 do not operate, and thus driving of the speaker is halted.

That is, according to the speaker protection circuit shown in FIG. 1, in the case where a voltage of the reference bias terminal 5 drops abnormally due to, for example, leakage in an electronic component (capacitor 2) connected to the reference bias terminal 5 and a short circuit between the reference bias terminal 5 and a ground line, driving of the speaker 21 is halted immediately. As a result, the flow of an offset current through the speaker 21 is suppressed, which can avoid damage to the speaker 21 caused by an excessively large offset current.

Furthermore, it is possible to realize a speaker protection circuit using a relatively simple circuit configuration including the voltage comparator 30, the first switching element 32, the second switching element 33 and the like. For example, the speaker protection circuit is incorporated in an integrated circuit and thus can contribute to a size reduction of a BTL amplifying device as a whole.

The threshold voltage V1 of the voltage comparator 30 is preset taking into consideration permissible fluctuations in the voltage of the reference bias terminal 5 based on the following. That is, no problem arises when fluctuations due to variations in the accuracy of components constituting the bias circuit 7 and the degree of leakage in the reference bias terminal 5 or a capacitor connected to the reference bias terminal 5 are minimal, and an offset voltage generated between the output terminals B1 and B2 under these circumstances falls within such a range that the speaker 21 is not damaged nor affected adversely. With this in view, based on an experiment or the like, the threshold voltage V1 is preset to such a value that the voltage comparator 30 does not have a low level output when voltage fluctuations are in such a permissible range.

In the above-described embodiment, in the case where the voltage comparator 30 has a low level output, both of the switching elements 32 and 33 are turned off to cut off a current supply to each of the power amplifying circuits 15 and 16 so that driving of the speaker by the power amplifying circuits 15 and 16 is halted. However, since the speaker 21 is driven by a BTL amplifying circuit including the power amplifying circuits 15 and 16, even a configuration in which a current supply to either of the power amplifying circuits 15 and 16 is cut off allows driving of the speaker 21 to be halted. That is, it is sufficient that at least one of the switching elements 32 and 33 is turned off.

Furthermore, in the above-described embodiment, a configuration also is possible in which a flip-flop circuit is provided between an output of the voltage comparator 30 and a control input for the switching elements 32 and 33 so that the output of the voltage comparator 30 hardly is subjected to the influence of chattering, noise or the like. That is, the provision of the flip-flop circuit allows the switching elements 32 and 33 to be configured so as not to respond (malfunction) with respect to a change in level that occurs in a very short time such as noise.

### Second Embodiment

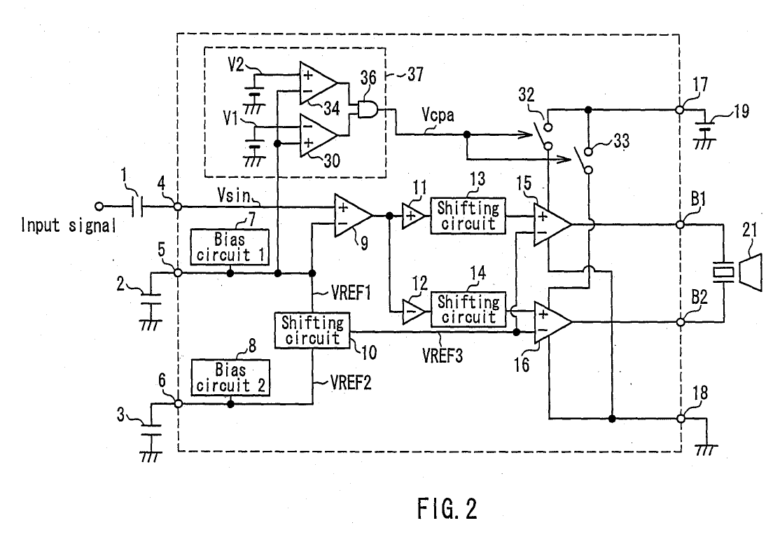

FIG. 2 is a circuit diagram of a BTL amplifying device including a speaker protection circuit according to a second embodiment of the present invention. In FIG. 2, like reference characters indicate the same constituent elements as in the first embodiment shown in FIG. 1, for which duplicate descriptions are omitted. The following description focuses on newly added constituent elements in a circuit shown in FIG. 2.

In FIG. 2, a second voltage comparator 34 compares a first reference voltage VREF1 with a second threshold voltage V2. The second threshold voltage V2 is set to a value larger than a threshold voltage (first threshold voltage) V1 of a first voltage comparator 30. That is, a relationship V1<V2 is established.

Furthermore, an AND circuit 36 performs an AND operation on an output signal of the first voltage comparator 30 and an output signal of the second voltage comparator 34. An output signal Vcpa of the AND circuit 36 is inputted to a control terminal of each of switching elements 32 and 33.

The following describes an operation of the speaker protection circuit in the second embodiment.

In FIG. 2, the circuit operation from the step in which an input signal is inputted through the step performed in level shifting circuits 13 and 14 and the operation in which a speaker 21 is driven by a first power amplifying circuit 15 and a second power amplifying circuit 16 are the same as those in the first embodiment shown in FIG. 1. However, the switching elements 32 and 33 are controlled differently from the first embodiment.

While being compared with the first threshold voltage V1 by the first voltage comparator 30, the reference voltage VREF1 is compared with the second threshold voltage V2 by the second voltage comparator 34.

When the reference voltage VREF 1 is lower than the first threshold voltage V1, the first voltage comparator 30 outputs a low level voltage. When the reference voltage VREF 1 is higher than the second threshold voltage V2, the second voltage comparator 34 outputs a low level voltage. Therefore, the output voltage Vcpa of the AND circuit 36 to which output signals of the first voltage comparator 30 and the second voltage comparator 34 are inputted is at a high level where V1≦VREF1≦V2 and is at a low level where VREF1<V1 or V2<VREF1.

In the case where the output voltage Vcp a of the AND circuit 36 is at a high level, the switching elements 32 and 33 are turned on, and thus the power amplifying circuits 15 and 16 are supplied with a power supply current, so that the speaker 21 is driven by operations of the power amplifying circuits 15 and 16. On the other hand, when the output voltage Vcpa of the AND circuit 36 is at a low level, the switching elements 32 and 33 are turned off, and thus the power amplifying circuits 15 and 16 are not supplied with a power supply current, so that driving of the speaker 21 is halted.

That is, according to the configuration of the second embodiment shown in FIG. 2, in addition to the effect of the first embodiment, the following effect is achieved. That is, also when a voltage of a reference bias terminal 5 rises abnormally due to, for example, a short circuit between the reference bias terminal 5 and a power supply line, driving of the speaker 21 can be halted immediately. As a result, the flow of an offset current through the speaker 21 is suppressed, which can avoid damage to the speaker 21 caused by an excessively large offset current.

The first threshold voltage V1 and the second threshold voltage V2 are preset taking into consideration permissible fluctuations in the voltage of the reference bias terminal 5 based on the following. That is, no problem arises in the case where fluctuations due to variations in the accuracy of components constituting a bias circuit 7 and the degree of leakage in the reference bias terminal 5 or a capacitor connected to the reference bias terminal 5 are minimal, and an offset voltage generated between output terminals B1 and B2 under these circumstances falls within such a range that the speaker 21 is not damaged nor affected adversely. With this in view, based on an experiment or the like, the first and second threshold voltages V1 and V2 are preset to such values that the output voltage Vcp a of the AND circuit 36 is not at a low level when voltage fluctuations are in such a permissible range.

In the above-described embodiment, when the output voltage Vcpa of the AND circuit 36 is at a low level, both of the first and second switching elements 32 and 33 are turned off to cut off a current supply to each of the power amplifying circuits 15 and 16 so that driving of the speaker by the power amplifying circuits 15 and 16 is halted. However, since the speaker 21 is driven by the BTL configuration of the power amplifying circuits 15 and 16, even a configuration in which a current supply to either of the power amplifying circuits 15 and 16 is cut off allows driving of the speaker to be halted. That is, it is sufficient that at least one of the switching elements 32 and 33 is turned off.

Furthermore, in the above-described embodiment, a configuration also is possible in which a flip-flop circuit is provided between an output of the AND circuit 36 and a control input for the switching elements 32 and 33 so that the output of the AND circuit 36 hardly is subjected to the influence of chattering, noise or the like. That is, the provision of the flip-flop circuit allows the switching elements 32 and 33 to be configured so as not to respond (malfunction) with respect to a change in level that occurs in a very short time such as noise.

Moreover, in FIG. 2, a configuration 37 composed of the first voltage comparator 30, the second voltage comparator 34 and the AND circuit 36 forms a well-known window comparator. However, this specific configuration of the window comparator 37 is not limited to the circuit shown as an example in FIG. 2, and it also is possible to achieve the same function using another circuit configuration.

### Third Embodiment

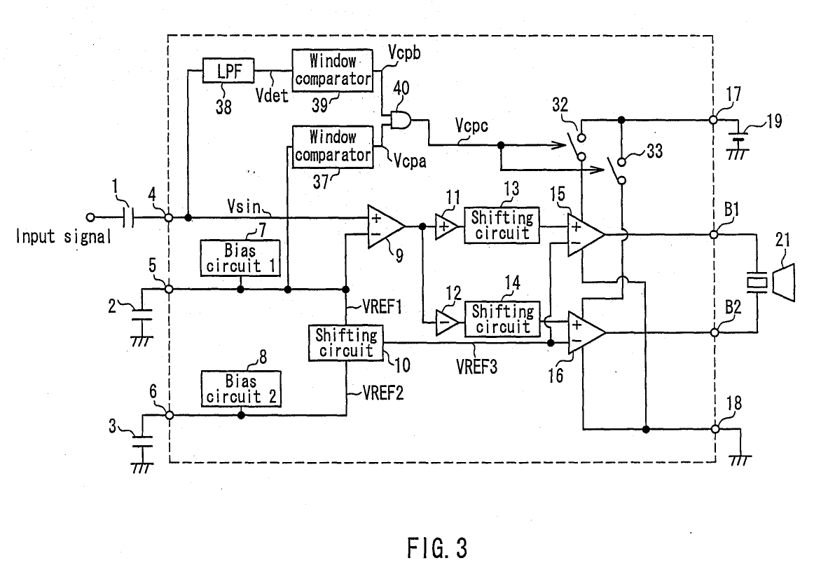

FIG. 3 is a circuit diagram of a BTL amplifying device including a speaker protection circuit according to a third embodiment of the present invention. In FIG. 3, like reference characters indicate the same members as in the second embodiment shown in FIG. 2, for which duplicate descriptions are omitted. The following description focuses on newly added member in a circuit shown in FIG. 3.

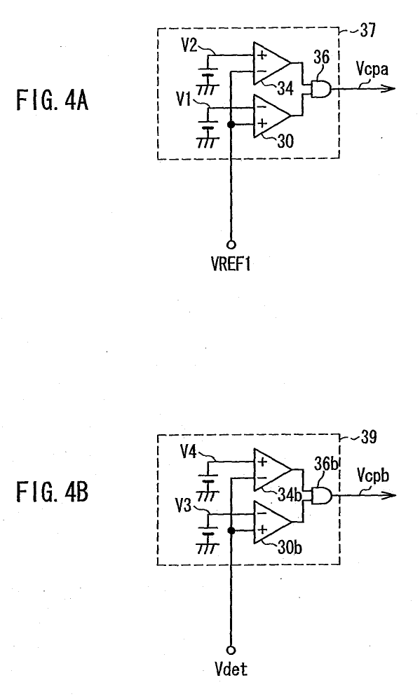

In the circuit shown in FIG. 3, a window comparator 37 is configured in the same manner as described in the second embodiment, and a specific example of a circuit configuration thereof is shown in FIG. 4A. Further, a second window comparator 39 having the same configuration as that of the window comparator 37 is added in the circuit shown in FIG. 3, and a specific example of a circuit configuration thereof is shown in FIG. 4B.

Furthermore, a low-pass filter 38 is provided that smooths a signal Vsin of an input terminal 4 and outputs a DC voltage, and an output voltage Vdet of the low-pass filter 38 is inputted to the second window comparator 39. Moreover, an AND circuit 40 is provided that generates an AND of an output Vcpa of the window comparator 37 and an output Vcpb of the second window comparator and outputs the AND, and an output voltage Vcpc of the AND circuit 40 is used as a control input for switching elements 32 and 33.

As shown in FIG. 4B, the second window comparator 39 includes a third voltage comparator 30b, a fourth voltage comparator 34b and an AND circuit 36b. The third voltage comparator 30b compares the output voltage Vdet of the low-pass filter 38 with a third threshold voltage V3, and the fourth voltage comparator 34b compares the output voltage Vdet of the low-pass filter 38 with a fourth threshold voltage V4. The fourth threshold voltage V4 is set to a value larger than a value of the third threshold voltage V3. That is, a relationship V3<V4 is established. An AND of an output of the third voltage comparator 30b and an output of the fourth voltage comparator 34b is generated in the AND circuit 36b, and an output of the AND circuit 36b is inputted to the AND circuit 40 as an output of the second window comparator 39.

The following describes an operation of the speaker protection circuit according to the third embodiment.

In FIG. 3, the circuit operation from the step in which an input signal is inputted through the step performed in level shifting circuits 13 and 14 and the operation in which a speaker 21 is driven by a first power amplifying circuit 15 and a second power amplifying circuit 16 are the same as those in the first embodiment shown in FIG. 1. Further, in the window comparator 37, a reference voltage VREF1 is compared with each of a first threshold voltage V1 and a second threshold voltage V2, and the output voltage Vcpa is outputted. The output voltage Vcpa is at a high level where V1≦VREF1≦V2 and is at a low level where VREF1<V1 or V2<VREF1. This relationship is the same as in the case of the circuit of the second embodiment shown in FIG. 2.

Moreover, in this embodiment, the signal Vsin inputted from the input terminal 4 is smoothed by the low-pass filter 38, and the output voltage Vdet of the low-pass filter 38 is inputted to the second window comparator 39. The window comparator 39 compares the output voltage Vdet of the low-pass filter 38 with each of the threshold voltages V3 and V4 and outputs the output voltage Vcpb as a result of the comparison. That is, the output voltage Vcpb is at a high level where V3≦Vdet≦V4 and is at a low level where Vdet<V3 or V4<Vdet.

In the case where both the output voltage Vcpa of the first window comparator 37 and the output voltage Vcpb of the second window comparator 39 are at a high level, the output voltage Vcpc of the AND circuit 40 is at a high level, so that the first switching element 32 and the second switching element 33 are turned on, and thus the first power amplifying circuit 15 and the second power amplifying circuit 16 are supplied with a power supply current. Thus, the first power amplifying circuit 15 and the second power amplifying circuit 16 drive the speaker 21 upon receipt of signals whose phases are inverted from each other. On the other hand, in the case where at least one of the output voltage Vcpa of the first window comparator 37 and the output voltage Vcpb of the second window comparator 39 is at a low level, the output voltage Vcpc of the AND circuit 40 is at a low level, so that the first switching element 32 and the second switching element 33 are turned off, and thus the first power amplifying circuit 15 and the second power amplifying circuit 16 are not supplied with a power supply current. Thus, driving of the speaker 21 is halted.

That is, according to the configuration of the third embodiment shown in FIG. 3, in addition to the effect of the second embodiment, the following effect is achieved. That is, also in the case where a DC component of the voltage Vsin of the input terminal drops or rises abnormally, driving of the speaker 21 can be halted immediately. As a result, the flow of an offset current through the speaker 21 is suppressed, which can avoid the possibility that the speaker 21 is damaged by an excessively large offset current.

In the same manner as in the case of the first threshold voltage V1 and the second threshold voltage V2, the third threshold voltage V3 and the fourth threshold voltage V4 are preset taking into consideration permissible fluctuations in the voltage of a reference bias terminal 5 based on the following. That is, no problem arises in the case where an offset voltage generated between output terminals B1 and B2 falls within such a range that the speaker 21 is not damaged nor affected adversely. With this in view, based on an experiment or the like, values of the third threshold voltage V3 and the fourth threshold voltage V4 are preset to such a value that the output voltage Vcpb of the AND circuit 36b is not at a low level when voltage fluctuations are in such a permissible range.

In the above-described embodiment, when the output voltage Vcpc of the AND circuit 40 is at a low level, both of the first switching element 32 and the second switching element 33 are turned off to cut off a current supply to each of the power amplifying circuits 15 and 16 so that driving of the speaker 21 by the power amplifying circuits 15 and 16 is halted. However, since the speaker 21 is driven by the BTL configuration of the power amplifying circuits 15 and 16, even a configuration in which a current supply to either of the power amplifying circuits 15 and 16 is cut off allows driving of the speaker 21 to be halted. That is, it is sufficient that at least one of the switching elements 32 and 33 is turned off.

Furthermore, in the above-described embodiment, a configuration also is possible in which a flip-flop circuit is provided between an output of the AND circuit 36 and a control input for the switching elements 32 and 33 so that the output of the AND circuit 36 hardly is subjected to the influence of chattering, noise or the like. That is, the provision of the flip-flop circuit allows the switching elements 32 and 33 to be configured so as not to respond (malfunction) with respect to a change in level that occurs in a very short time such as noise.

### Fourth Embodiment

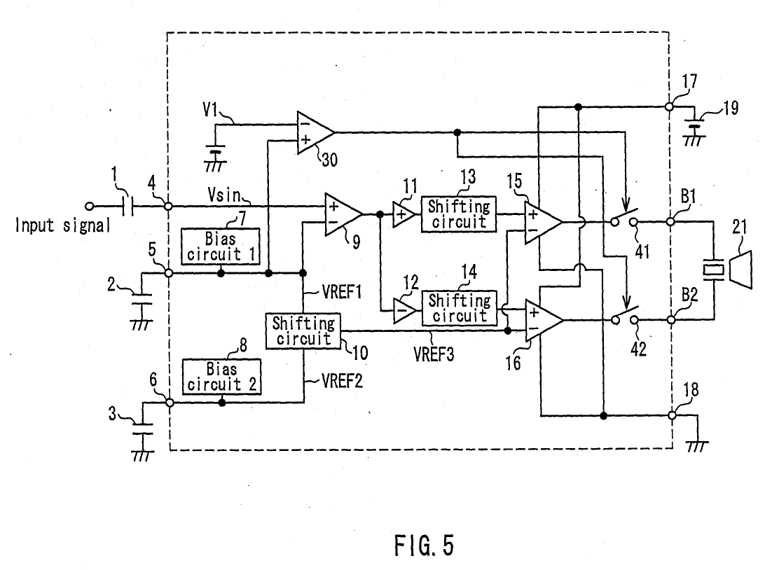

FIG. 5 is a circuit diagram of a BTL amplifying device including a speaker protection circuit according to a fourth embodiment of the present invention. In FIG. 5, like reference characters indicate the same members as in the first embodiment shown in FIG. 1, for which duplicate descriptions are omitted. The following is a description of this embodiment focusing on differences from the first embodiment shown in FIG. 1.

In a circuit shown in FIG. 5, the first switching element 32 and the second switching element 33 in FIG. 1 are removed, and instead, a first switching element 41 is connected between an output of a first power amplifying circuit 15 and a speaker 21, while a second switching element 42 is connected between an output of a second power amplifying circuit 16 and the speaker 21.

The following describes an operation of the speaker protection circuit according to the fourth embodiment.

In FIG. 5, the circuit operation from the step in which an input signal is inputted through the step performed in level shifting circuits 13 and 14 and the operation in which the speaker 21 is driven by the first power amplifying circuit 15 and the second power amplifying circuit 16 are the same as those in the first embodiment shown in FIG. 1. A voltage comparator 30 compares a reference voltage VREF1 with a threshold voltage V1. In the case where the reference voltage VREF1 is not lower than the threshold voltage V1, the voltage comparator 30 outputs a high level voltage, so that the first switching element 41 and the second switching element 42 are turned on. Thus, a driving current from each of the power amplifying circuits 15 and 16 is supplied to the speaker 21, so that the speaker 21 is driven.

Conversely, in the case where the reference voltage VREF 1 is lower than the threshold voltage V1, a low level voltage is outputted from the voltage comparator 30, so that the switching elements 41 and 42 are turned off. Thus, a driving current from each of outputs of the power amplifying circuits 15 and 16 to the speaker 21 is cut off, causing the speaker 21 not to be driven any more.

That is, according to the configuration of the fourth embodiment shown in FIG. 5, similarly to the first embodiment, in the case where a voltage of a reference bias terminal 5 drops abnormally due to, for example, leakage in an electronic component 2 connected to the reference bias terminal 5 and a short circuit between the reference bias terminal 5 and a ground line, driving of the speaker 21 is halted immediately. As a result, the flow of an offset current through the speaker 21 is suppressed, which can avoid the possibility that the speaker 21 is damaged by an excessively large offset current.

Furthermore, it is possible to realize a speaker protection circuit using a relatively simple circuit configuration including the voltage comparator 30, the first switching element 41, the second switching element 42 and the like. For example, the speaker protection circuit is incorporated in an integrated circuit and thus can contribute to a size reduction of a BTL amplifying device as a whole.

In the above-described embodiment, in the case where the voltage comparator 30 has a low level output, both of the switching elements 41 and 42 are turned off to cut off a current supply from each of the power amplifying circuits 15 and 16 to the speaker 21 so that driving of the speaker 21 is halted. However, since the speaker 21 is driven by the BTL configuration of the power amplifying circuits 15 and 16, even a configuration in which a current supply from either of the power amplifying circuits 15 and 16 to the speaker 21 is cut off allows driving of the speaker 21 to be halted. That is, it is sufficient that at least one of the switching elements 41 and 42 is turned off.

Furthermore, in the above-described embodiment, a configuration also is possible in which a flip-flop circuit is provided between an output of the voltage comparator 30 and a control input for the switching elements 41 and 42 so that the output of the voltage comparator 30 hardly is subjected to the influence of chattering, noise or the like. That is, thanks to the functioning of the flip-flop circuit, the switching elements 41 and 42 can be configured so as not to respond (malfunction) with respect to a change in level that occurs in a very short time such as noise.

### Fifth Embodiment

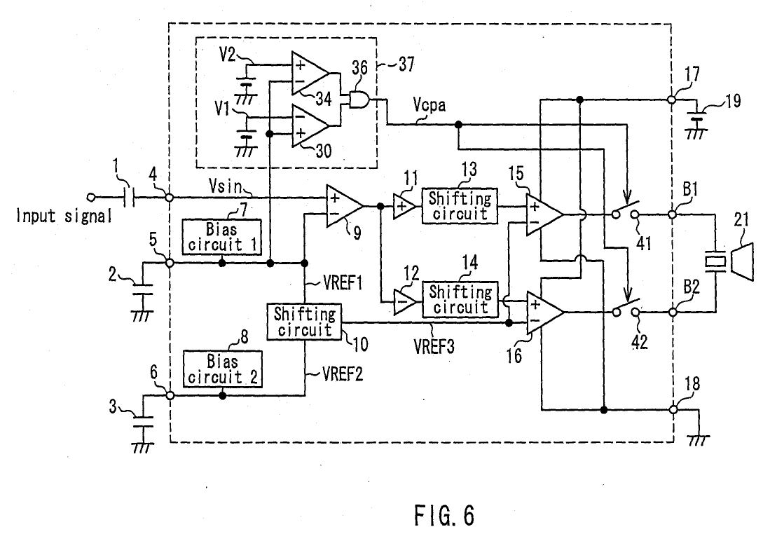

FIG. 6 is a circuit diagram of a BTL amplifying device including a speaker protection circuit according to a fifth embodiment of the present invention. In FIG. 6, like reference characters indicate the same members as in the fourth embodiment shown in FIG. 5, for which duplicate descriptions are omitted. The following description focuses on members newly added to the circuit shown in FIG. 5.

In a circuit shown in FIG. 6, a second voltage comparator 34 is provided that compares a first reference voltage VREF1 with a second threshold voltage V2. The second threshold voltage V2 is set to a value larger than a threshold voltage (first threshold voltage) V1 of a first voltage comparator 30. That is, a relationship V1<V2 is established. Further, an AND circuit 36 is provided that generates an AND of an output of the first voltage comparator 30 and an output of the second voltage comparator 34, and an output Vcpa of the AND circuit 36 is used as a control input for switching elements 41 and 42.

The following describes an operation of the speaker protection circuit according to the fifth embodiment.

In FIG. 6, the circuit operation from the step in which an input signal is inputted through the step performed in level shifting circuits 13 and 14 and the operation in which a speaker 21 is driven by a first power amplifying circuit 15 and a second power amplifying circuit 16 are the same as those in the fourth embodiment shown in FIG. 5. However, the switching elements 41 and 42 are controlled differently from the fourth embodiment. While being compared with the first threshold voltage V1 by the first voltage comparator 30, the reference voltage VREF1 is compared with the second threshold voltage V2 by the second voltage comparator 34.

When the reference voltage VREF 1 is lower than the first threshold voltage V1, the first voltage comparator 30 outputs a low level voltage. Further, when the reference voltage VREF1 is higher than the second threshold voltage V2, the second voltage comparator 34 outputs a low level voltage. Therefore, the output voltage Vcpa of the AND circuit 36 to which outputs of the first voltage comparator 30 and the second voltage comparator 34 are inputted is at a high level where V1≦VREF1≦V2 and is at a low level where VREF1<V1 or V2<VREF1.

In the case where the output voltage Vcpa of the AND circuit 36 is at a high level, the switching elements 41 and 42 are turned on, and thus a driving current from each of the power amplifying circuits 15 and 16 is supplied to the speaker 21, so that the speaker 21 is driven. Conversely, when the output voltage Vcpa is at a low level, the switching elements 41 and 42 are turned off, and thus a driving current from each of the power amplifying circuits 15 and 16 to the speaker 21 is cut off, so that driving of the speaker 21 is halted.

That is, according to the configuration of the fifth embodiment shown in FIG. 6, in addition to the effect of the first embodiment, the following effect is achieved. That is, also when a voltage of a reference bias terminal 5 rises abnormally due to, for example, a short circuit between the reference bias terminal 5 and a power supply line, driving of the speaker 21 can be halted immediately. As a result, the flow of an offset current through the speaker 21 is suppressed, which can avoid the possibility that the speaker 21 is damaged by an excessively large offset current.

In the above-described embodiment, in the case where the output voltage Vcpa of the AND circuit 36 is at a low level, both of the switching elements 41 and 42 are turned off to cut off a driving current from each of the power amplifying circuits 15 and 16 to the speaker 21 so that driving of the speaker 21 is halted. However, since the speaker 21 is driven by the BTL configuration of the power amplifying circuits 15 and 16, even a configuration in which a driving current from either of the power amplifying circuits 15 and 16 to the speaker 21 is cut off allows driving of the speaker 21 to be halted. That is, it is sufficient that at least one of the switching elements 41 and 42 is turned off.

Furthermore, in the above-described embodiment, a configuration also is possible in which a flip-flop circuit is provided between an output of the AND circuit 36 and a control input for the switching elements 41 and 42 so that the output of the AND circuit 36 hardly is subjected to the influence of chattering, noise or the like. That is, the provision of the flip-flop circuit allows the switching elements 41 and 42 to be configured so as not to respond (malfunction) with respect to a change in level that occurs in a very short time such as noise.

### Sixth Embodiment

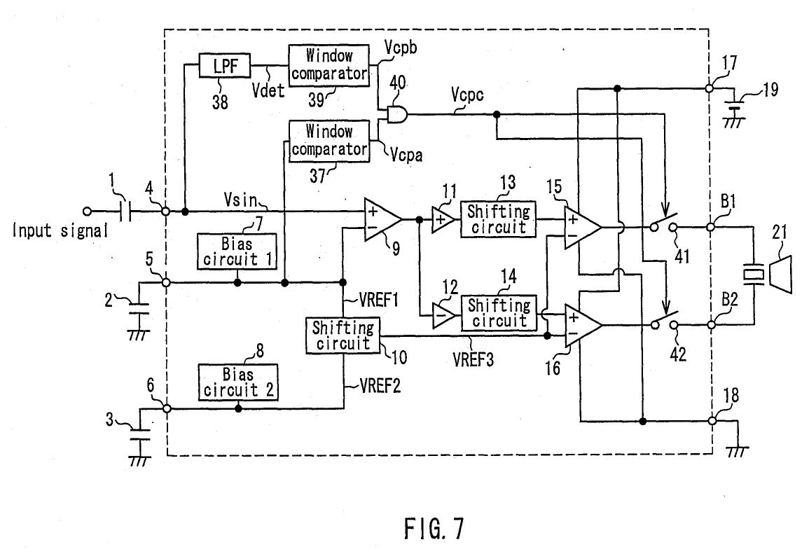

FIG. 7 is a circuit diagram of a BTL amplifying device including a speaker protection circuit according to a sixth embodiment of the present invention. In FIG. 7, like reference characters indicate the same members as in the fifth embodiment shown in FIG. 6, for which duplicate descriptions are omitted. The following description focuses on members newly added to the circuit shown in FIG. 6.

In FIG. 7, a first window comparator 37 is configured in the same manner as described in the third embodiment (see FIG. 4A), and a second window comparator 39 having the same configuration (see FIG. 4B) as that of the first window comparator 37 is added.

Furthermore, a low-pass filter 38 is provided that smooths a signal Vsin of an input terminal 4 and outputs a DC voltage, and an output voltage Vdet of the low-pass filter 38 is inputted to the second window comparator 39. Moreover, an AND circuit 40 is provided that generates an AND of an output Vcpa of the first window comparator 37 and an output Vcpb of the second window comparator 39 and outputs the AND, and an output voltage Vcpc of the AND circuit 40 is used as a control input for switching elements 41 and 42.

Similarly to the third embodiment shown in FIGS. 3 and 4, the second window comparator 39 compares the output voltage Vdet of the low-pass filter 38 with each of a third threshold voltage V3 and a fourth threshold voltage V4 (where V3<V4) and inputs the comparative output Vcpb to the AND circuit 40.

The following describes an operation of the speaker protection circuit according to the sixth embodiment.

In FIG. 7, the circuit operation from the step in which an input signal is inputted through the step performed in level shifting circuits 13 and 14 and the operation in which a speaker 21 is driven by a first power amplifying circuit 15 and a second power amplifying circuit 16 are the same as those in the fourth embodiment shown in FIG. 5. Further, a reference voltage VREF1 is compared with each of a first threshold voltage V1 and a second threshold voltage V2 by the window comparator 37, and the output voltage Vcpa is outputted. The output voltage Vcpa is at a high level where V1≦VREF1≦V2 and is at a low level where VREF1<V1 or V2<VREF1.

Moreover, in this embodiment, a signal Vsin inputted from an input terminal 4 is smoothed by the low-pass filter 38, and the output voltage Vdet of the low-pass filter 38 is inputted to the second window comparator 39. The second window comparator 39 compares the output voltage Vdet of the low-pass filter 38 with each of the threshold voltages V3 and V4 and outputs the output voltage Vcpb as a result of the comparison. That is, the output voltage Vcpb is at a high level where V3≦Vdet≦V4 and is at a low level where Vdet<V3 or V4<Vdet.

In the case where both the output voltage Vcpa of the first window comparator 37 and the output voltage Vcpb of the second window comparator 39 are at a high level, the output voltage Vcpc of the AND circuit is at a high level, so that the switching elements 41 and 42 are turned on. Thus, a driving current from each of the power amplifying circuits 15 and 16 is supplied to the speaker 21, so that the speaker 21 is driven.

Conversely, in the case where at least one of the output voltage Vcpa and the output voltage Vcpb is at a low level, the output voltage Vcpc is at a low level, so that the switching elements 41 and 42 are turned off. Thus, a driving current from each of outputs of the power amplifying circuits 15 and 16 to the speaker 21 is cut off, so that driving of the speaker 21 is halted.

That is, according to the configuration of the sixth embodiment shown in FIG. 7, in addition to the effect of the fifth embodiment, the following effect is achieved. That is, also in the case where a DC component of the voltage Vsin of the input terminal drops or rises abnormally, driving of the speaker 21 can be halted immediately. As a result, the flow of an offset current through the speaker 21 is suppressed, which can avoid the possibility that the speaker 21 is damaged by an excessively large offset current.

In the above-described embodiment, in the case where the output voltage Vcpc of the AND circuit 40 is at a low level, both of the switching elements 41 and 42 are turned off to cut off a driving current from each of the power amplifying circuits 15 and 16 to the speaker 21 so that driving of the speaker 21 is halted. However, since the speaker 21 is driven by the BTL configuration of the power amplifying circuits 15 and 16, even a configuration in which a driving current from either of the power amplifying circuits 15 and 16 to the speaker 21 is cut off allows driving of the speaker 21 to be halted. That is, it is sufficient that at least one of the switching elements 41 and 42 is turned off.

Furthermore, in the above-described embodiment, a configuration also is possible in which a flip-flop circuit is provided between an output of the AND circuit 40 and a control input for the switching elements 41 and 42 so that the output of the AND circuit 40 hardly is subjected to the influence of chattering, noise or the like. That is, the provision of the flip-flop circuit allows the switching elements 41 and 42 to be configured so as not to respond (malfunction) with respect to a change in level that occurs in a very short time such as noise.

### Seventh Embodiment

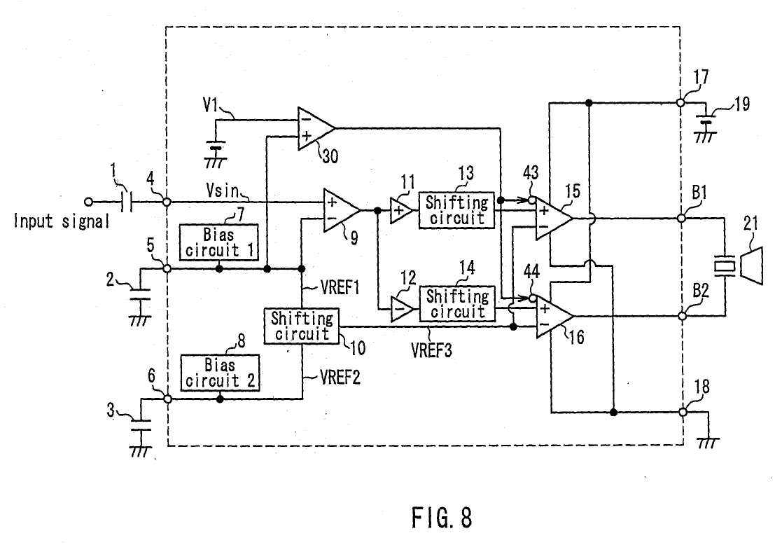

FIG. 8 is a circuit diagram of a BTL amplifying device including a speaker protection circuit according to a seventh embodiment of the present invention. In FIG. 8, like reference characters indicate the same members as in the first embodiment shown in FIG. 1, for which duplicate descriptions are omitted. The following is a description of this embodiment focusing on differences from the first embodiment shown in FIG. 1.

In a circuit shown in FIG. 8, the first switching element 32 and the second switching element 33 in FIG. 1 are removed. Instead, a muting circuit that halts an amplifying operation is included in each of a first power amplifying circuit 15 and a second power amplifying circuit 16, and mute terminals 43 and 44 for allowing the muting circuit to operate are provided. When a low level signal is inputted to the mute terminal 43 or 44, an amplifying operation of the power amplifying circuit 15 or 16 is halted. That is, the muting circuit functions (hereinafter, this state is referred to as a mute-on state). When the mute terminal 43 or 44 is at a high level, the muting circuits do not function, so that the power amplifying circuits 15 and 16 are brought into a normal operating state (hereinafter, referred to as a mute-off state).

The following describes an operation of the speaker protection circuit according to the seventh embodiment.

In FIG. 8, the circuit operation from the step in which an input signal is inputted through the step performed in level shifting circuits 13 and 14 and the operation in which a speaker 21 is driven by the first power amplifying circuit 15 and the second power amplifying circuit 16 are the same as those in the first embodiment shown in FIG. 1. A voltage comparator 30 compares a reference voltage VREF1 with a threshold voltage V1. In the case where the reference voltage VREF1 is not lower than the threshold voltage V1, the voltage comparator 30 outputs a high level voltage. Thus, the power amplifying circuits 15 and 16 are brought into the mute-off state, and signals whose phases are inverted from each other are received, so that the speaker 21 is driven.

Conversely, in the case where the reference voltage VREF1 is lower than the threshold voltage V1, the voltage comparator 30 outputs a low level voltage, and thus the power amplifying circuits 15 and 16 are brought into the mute-on state, so that driving of the speaker 21 is halted.

That is, according to the configuration of the seventh embodiment shown in FIG. 8, similarly to the first embodiment, in the case where a voltage of a reference bias terminal 5 drops abnormally due to, for example, leakage in an electronic component 2 connected to the reference bias terminal 5 and a short circuit between the reference bias terminal 5 and a ground line, driving of the speaker 21 is halted immediately. As a result, the flow of an offset current through the speaker 21 is suppressed, which can avoid the possibility that the speaker 21 is damaged by an excessively large offset current.

Furthermore, it is possible to realize a speaker protection circuit using a relatively simple circuit configuration including the voltage comparator 30. For example, the speaker protection circuit is incorporated in an integrated circuit and thus can contribute to a size reduction of a BTL amplifying device as a whole.

In the above-described embodiment, in the case where the voltage comparator 30 has a low level output, both of the power amplifying circuits 15 and 16 are brought into the mute-on state so that driving of the speaker 21 is halted. However, since the speaker 21 is driven by the BTL configuration of the power amplifying circuits 15 and 16, a configuration in which only either one of the power amplifying circuits 15 and 16 is brought into the mute-on state allows driving of the speaker 21 to be halted. That is, it is sufficient that at least one of the power amplifying circuits 15 and 16 is brought into the mute-on state.

Furthermore, in the above-described embodiment, a configuration also is possible in which a flip-flop circuit is provided between an output of the voltage comparator 30 and the mute terminals 43 and 44 so that the output of the voltage comparator 30 hardly is subjected to the influence of chattering, noise or the like. That is, thanks to the functioning of the flip-flop circuit, the muting circuit provided in each of the power amplifying circuits 15 and 16 can be configured so as not to respond (malfunction) with respect to a change in level that occurs in a very short time such as noise.

### Eighth Embodiment

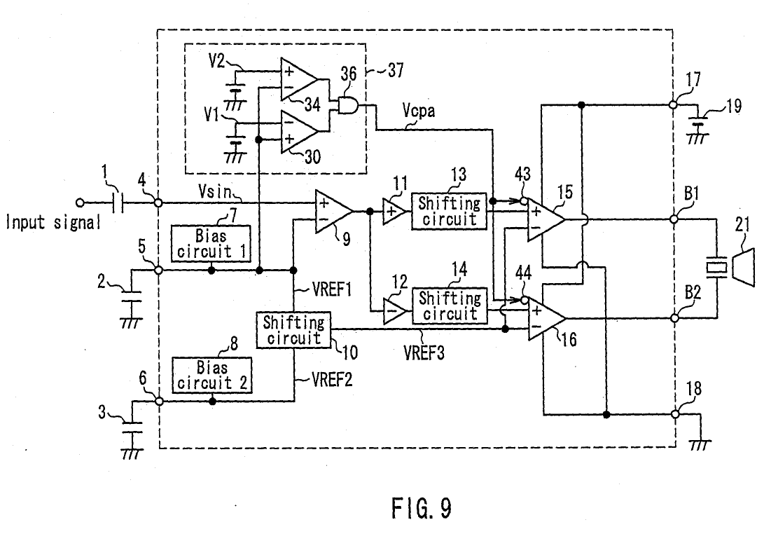

FIG. 9 is a circuit diagram of a BTL amplifying device including a speaker protection circuit according to an eighth embodiment of the present invention. In FIG. 9, like reference characters indicate the same members as in the seventh embodiment shown in FIG. 8, for which duplicate descriptions are omitted. The following only describes members newly added to the speaker protection circuit shown in FIG. 8.

In a circuit shown in FIG. 9, a second voltage comparator 34 is provided that compares a first reference voltage VREF1 with a second threshold voltage V2. The second threshold voltage V2 is set to a value larger than a threshold voltage (first threshold voltage) V1 of a first voltage comparator 30. That is, a relationship V1<V2 is established. Further, an AND circuit 36 is provided that generates an AND of an output of the first voltage comparator 30 and an output of the second voltage comparator 34, and an output Vcpa of the AND circuit 36 is connected to each of a mute terminal 43 of a power amplifying circuit 15 and a mute terminal 44 of a power amplifying circuit 16.

The following describes an operation of the speaker protection circuit according to the eighth embodiment.

In FIG. 9, the circuit operation from the step in which an input signal is inputted through the step performed in level shifting circuits 13 and 14 and the operation in which a speaker 21 is driven by the first power amplifying circuit 15 and the second power amplifying circuit 16 are the same as those in the seventh embodiment shown in FIG. 8.

In the eighth embodiment, a muting circuit provided in each of the power amplifying circuits 15 and 16 is controlled differently from the seventh embodiment. While being compared with the first threshold voltage V1 by the first voltage comparator 30, the reference voltage VREF1 is compared with the second threshold voltage V2 by the second voltage comparator 34.

When the reference voltage VREF 1 is lower than the first threshold voltage V1, the first voltage comparator 30 outputs a low level voltage. Further, when the reference voltage VREF1 is higher than the second threshold voltage V2, the second voltage comparator 34 outputs a low level voltage. Therefore, the output voltage Vcpa of the AND circuit 36 is at a high level where V1≦VREF1≦V2 and is at a low level where VREF1<V1 or V2<VREF1.

In the case where the output voltage Vcpa of the AND circuit 36 is at a high level, both of the power amplifying circuits 15 and 16 are brought into a mute-off state, and thus an output signal (driving current) of each of the power amplifying circuits 15 and 16 is supplied to the speaker 21, so that the speaker 21 is driven.

Conversely, when the output voltage Vcpa is at a low level, both of the power amplifying circuits 15 and 16 are bought into a mute-on state, so that driving of the speaker 21 by the power amplifying circuits 15 and 16 is halted.

That is, according to the configuration of the eighth embodiment shown in FIG. 9, in addition to the effect of the seventh embodiment, the following effect is achieved. That is, also when a voltage of a reference bias terminal 5 rises abnormally due to, for example, a short circuit between the reference bias terminal 5 and a power supply line, driving of the speaker 21 can be halted immediately. As a result, the flow of an offset current through the speaker 21 is suppressed, which can avoid the possibility that the speaker 21 is damaged by an excessively large offset current.

In the above-described embodiment, in the case where the output voltage Vcpa of the AND circuit 36 is at a low level, both of the power amplifying circuits 15 and 16 are brought into the mute-on state so that driving of the speaker 21 is halted. However, since the speaker 21 is driven by the BTL configuration of the power amplifying circuits 15 and 16, a configuration in which either of the power amplifying circuits 15 and 16 is brought into the mute-on state allows driving of the speaker 21 to be halted. That is, it is sufficient that at least one of the power amplifying circuits 15 and 16 is brought into the mute-on state.

Furthermore, in the above-described embodiment, a configuration also is possible in which a flip-flop circuit is provided between an output of the AND circuit 36 and the mute terminals 43 and 44 so that the output of the AND circuit 36 hardly is subjected to the influence of chattering, noise or the like. That is, thanks to the functioning of the flip-flop circuit, the muting circuit provided in each of the power amplifying circuits 15 and 16 can be configured so as not to respond (malfunction) with respect to a change in level that occurs in a very short time such as noise.

### Ninth Embodiment

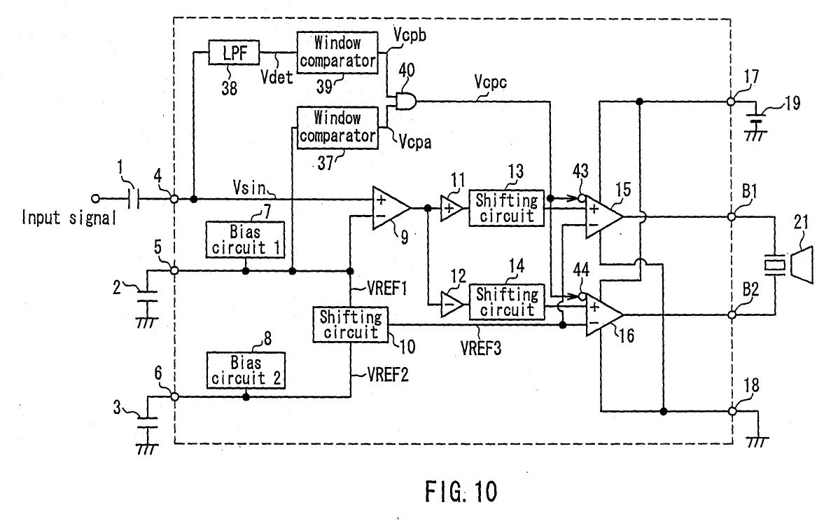

FIG. 10 is a circuit diagram of a BTL amplifying device including a speaker protection circuit according to a ninth embodiment of the present invention. In FIG. 10, like reference characters indicate the same members as in the eighth embodiment shown in FIG. 9, for which duplicate descriptions are omitted. The following description focuses on members newly added to the circuit shown in FIG. 9.

In FIG. 10 a first window comparator 37 is configured in the same manner as described in the third embodiment (see FIG. 4A), and a second window comparator 39 having the same configuration (see FIG. 4B) as that of the first window comparator 37 is added.

Furthermore, a low-pass filter 38 is provided that smooths a signal Vsin of an input terminal 4 and outputs a DC voltage, and an output voltage Vdet of the low-pass filter 38 is inputted to the second window comparator 39. Moreover, an AND circuit 40 is provided that generates an AND of an output Vcpa of the first window comparator 37 and an output Vcpb of the second window comparator 39 and outputs the AND, and an output voltage Vcpc of the AND circuit 40 is connected to each of a mute terminal 43 of a power amplifying circuit 15 and a mute terminal 44 of a power amplifying circuit 16.

Similarly to the third embodiment shown in FIGS. 3 and 4, the second window comparator 39 compares the output voltage Vdet of the low-pass filter 38 with each of a third threshold voltage V3 and a fourth threshold voltage V4 (where V3<V4) and inputs the comparative output Vcpb to the AND circuit 40.

The following describes an operation of the speaker protection circuit according to the ninth embodiment.

In FIG. 10, the circuit operation from the step in which an input signal is inputted through the step performed in level shifting circuits 13 and 14 and the operation in which a speaker 21 is driven by the first power amplifying circuit 15 and the second power amplifying circuit 16 are the same as those in the seventh embodiment shown in FIG. 8. Further, in the first window comparator 37, a reference voltage VREF1 is compared with each of a first threshold voltage V1 and a second threshold voltage V2, and the output voltage Vcpa of the first window comparator 37 is at a high level where V1≦VREF1≦V2 and is at a low level where VREF1<V1 or V2<VREF1.

Moreover, in this embodiment, the signal Vsin inputted from the input terminal 4 is smoothed by the low-pass filter 38, and the output voltage Vdet of the low-pass filter 38 is inputted to the second window comparator 39. The second window comparator 39 compares the output voltage Vdet of the low-pass filter 38 with each of the threshold voltages V3 and V4 and outputs the output voltage Vcpb as a result of the comparison. That is, the output voltage Vcpb is at a high level where V3≦Vdet≦V4 and is at a low level where Vdet<V3 or V4<Vdet.

In the case where both of the output voltage Vcpa of the first window comparator 37 and the output voltage Vcpb of the second window comparator 39 are at a high level, the output voltage Vcpc of the AND circuit 40 is at a high level. This brings both of the power amplifying circuits 15 and 16 into a mute-off state, and thus an output signal (driving current) of each of the power amplifying circuits 15 and 16 is supplied to the speaker 21, so that the speaker 21 is driven.

Conversely, in the case where at least one of the output voltage Vcpa and the output voltage Vcpb is at a low level, the output voltage Vcpc of the AND circuit 40 is at a low level. This brings both of the power amplifying circuits 15 and 16 into a mute-on state, so that driving of the speaker 21 by the power amplifying circuits 15 and 16 is halted.

That is, according to the configuration of the ninth embodiment shown in FIG. 10, in addition to the effect of the eighth embodiment, the following effect is achieved. That is, also in the case where a DC component of the voltage Vsin of the input terminal drops or rises abnormally, driving of the speaker 21 can be halted immediately. As a result, a flow of an offset current through the speaker 21 is suppressed, which can avoid the possibility that the speaker 21 is damaged by an excessively large offset current.

In the above-described embodiment, in the case where the output voltage Vcpc of the AND circuit 40 is at a low level, both of the power amplifying circuits 15 and 16 are brought into the mute-on state so that driving of the speaker is halted. However, since the speaker 21 is driven by the BTL configuration of the power amplifying circuits 15 and 16, a configuration in which only either one of the power amplifying circuits 15 and 16 is brought into the mute-on state allows driving of the speaker 21 to be halted. That is, it is sufficient that at least one of the power amplifying circuits 15 and 16 is brought into the mute-on state.

Furthermore, in the above-described embodiment, a configuration also is possible in which a flip-flop circuit is provided between the AND circuit 40 and the mute terminals 43 and 44 so that an output of the AND circuit 40 hardly is subjected to the influence of chattering, noise or the like. That is, thanks to the functioning of the flip-flop circuit, a muting circuit provided in each of the power amplifying circuits 15 and 16 can be configured so as not to respond (malfunction) with respect to a change in level that occurs in a very short time such as noise.

### Tenth Embodiment

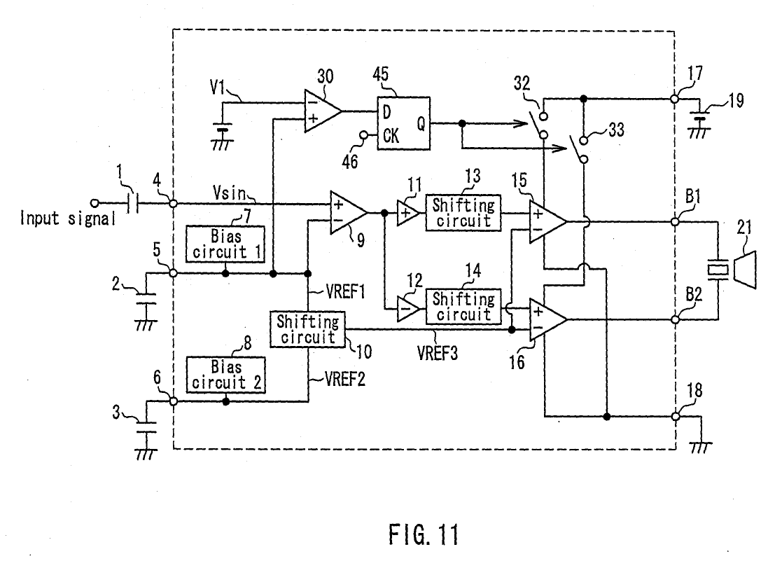

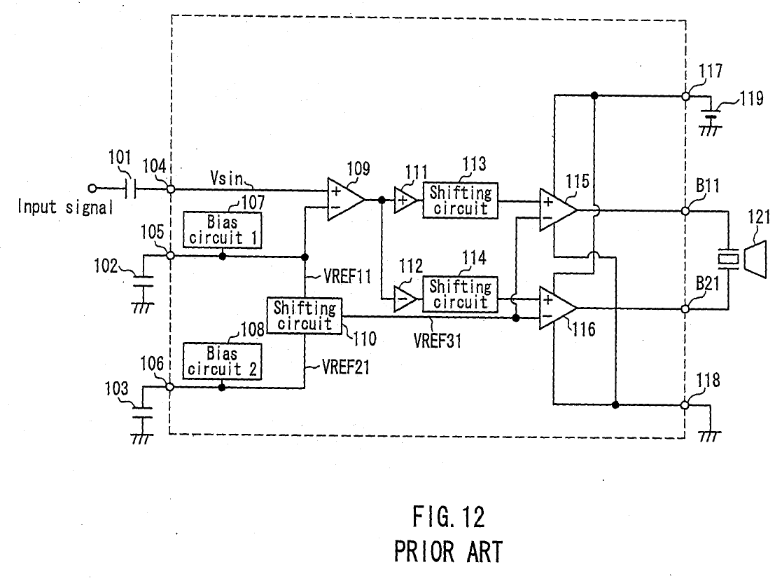

FIG. 11 is a circuit diagram of a BTL amplifying device including a speaker protection circuit according to a tenth embodiment of the present invention. In FIG. 11, like reference characters indicate the same members as in the first embodiment shown in FIG. 1, for which duplicate descriptions are omitted. The following description focuses on members newly added to the circuit shown in FIG. 10.

In a circuit shown in FIG. 11, a register circuit 45 is provided, and a predetermined reference clock is inputted to a dock input terminal 46 of the register circuit 45.

In FIG. 11, the circuit operation from the step in which an input signal is inputted through the step performed in level shifting circuits 13 and 14 and the operation in which a speaker 21 is driven by a first power amplifying circuit 15 and a second power amplifying circuit 16 are the same as those in the first embodiment shown in FIG. 1. However, switching elements 32 and 33 are controlled differently from the first embodiment. That is, unlike the first embodiment in which an output of the voltage comparator 30 is used in an as is state as a control input for the switching elements 32 and 33, the register circuit 45 is interposed between an output of a voltage comparator 30 and a control input for the switching elements 32 and 33. The register circuit 45 once stores an input signal at a constant cycle and then outputs an output signal according to a reference clock supplied to the clock input terminal 46.

According to the above-described configuration, when an output voltage of the voltage comparator 30 changes in a time period shorter than a cycle of a reference clock under an influence of chattering, noise or the like, such a change is not transmitted to an output of the register circuit 45 (namely, a control input for the switching elements 32 and 33). This can avoid a phenomenon in which the switching elements 32 and 33 respond (malfunction) with respect to a change in level that occurs in a very short time such as noise.

That is, according to the configuration of the tenth embodiment shown in FIG. 11, in addition to the effect of the first embodiment, the following effect is achieved. That is, malfunctioning due to a change in level that occurs in a very short time such as noise is prevented, and thus a highly reliable speaker protection circuit can be provided.

The configuration of this embodiment including the register circuit 45 may be combined with the fourth or seventh embodiment as well as the first embodiment. Also in such a case, the above-described effect can be obtained, and thus a highly reliable speaker protection circuit that withstands noise can be realized.

In the foregoing discussion, the present invention was described in detail by way of specific embodiments. However, the present invention is not limited to these embodiments and may be modified variously within a technical scope of the present invention.

Furthermore, each of the first to tenth embodiments includes the first switching element and the second switching element that allow an operation of the speaker to be halted. However, a configuration also is possible in which switching between a mode of supplying an electric current to each of the two power amplifying circuits and a mode of cutting off the electric current is done by means of a single switch. According to this configuration, an operation of a speaker can be halted by means of a single switch.

As described in the foregoing discussion, the speaker protection circuit of the present invention is useful as a circuit in an amplifying device of the BTL configuration, which is provided to protect a speaker driven by the amplifying device.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A speaker protection circuit for use in a BTL amplifying device that drives a speaker using two power amplifying circuits to which two signals whose phases are inverted from each other are inputted, respectively, comprising
a first voltage comparator that compares a voltage of a reference bias terminal of an amplifying circuit constituting the BTL amplifying device with a preset threshold voltage; and
a switch for switching between a mode of supplying an electric current to each of the two power amplifying circuits and a mode of cutting off the electric current,
wherein when the voltage of the reference bias terminal is lower than the threshold voltage, based on an output level of the first voltage comparator, the switch is turned off to cut off a current supply to each of the power amplifying circuits so that driving of the speaker by the power amplifying circuits is halted.

2. The speaker protection circuit according to claim 1, further comprising a second voltage comparator that compares the voltage of the reference bias terminal with a second threshold voltage higher than the threshold voltage,
wherein when the voltage of the reference bias terminal is higher than the second threshold voltage, based on an output level of the second voltage comparator, the switch is turned off to cut off the current supply to each of the power amplifying circuits so that the driving of the speaker by the power amplifying circuits is halted.

3. The speaker protection circuit according to claim 1, further comprising:
a low-pass filter that smooths a signal inputted from an input terminal and outputs a DC voltage;
a third voltage comparator that compares an output voltage of the low-pass filter with a third threshold voltage; and
a fourth voltage comparator that compares the output voltage of the low-pass filter with a fourth threshold voltage higher than the third threshold voltage,
wherein when the output voltage of the low-pass filter is lower than the third threshold voltage or higher than the fourth threshold voltage, the switch is turned off to cut off the current supply to each of the power amplifying circuits so that the driving of the speaker by the power amplifying circuits is halted.

4. The speaker protection circuit according to claim 1,
wherein a register that operates on a predetermined reference clock is provided within an output circuit of the first voltage comparator, and
an output voltage of the first voltage comparator is stored once in the register based on the reference clock and then is outputted from the register so that a change in the output voltage of the voltage comparator that occurs in a time period shorter than a cycle of the reference clock is not transmitted to a succeeding stage.

5. A speaker protection circuit for use in a BTL amplifying device that drives a speaker using two power amplifying circuits to which two signals whose phases are inverted from each other are inputted, respectively, comprising:
a first voltage comparator that compares a voltage of a reference bias terminal of an amplifying circuit constituting the BTL amplifying device with a preset threshold voltage; and
a switch that is interposed between the speaker and respective outputs of the two power amplifying circuits,
wherein when the voltage of the reference bias terminal is lower than the threshold voltage, based on an output level of the first voltage comparator, the switch is turned off to cut off a driving current from each of the power amplifying circuits to the speaker so that driving of the speaker is halted.

6. The speaker protection circuit according to claim 5, further comprising a second voltage comparator that compares the voltage of the reference bias terminal with a second threshold voltage higher than the threshold voltage,
wherein when the voltage of the reference bias terminal is higher than the second threshold voltage, based on an output level of the second voltage comparator, the switch is turned off to cut off the driving current from each of the power amplifying circuits to the speaker so that the driving of the speaker is halted.

7. The speaker protection circuit according to claim 5, further comprising:
a low-pass filter that smooths a signal inputted from an input terminal and outputs a DC voltage;
a third voltage comparator that compares an output voltage of the low-pass filter with a third threshold voltage; and
a fourth voltage comparator that compares the output voltage of the low-pass filter with a fourth threshold voltage higher than the third threshold voltage,
wherein when the output voltage of the low-pass filter is lower than the third threshold voltage or higher than the fourth threshold voltage, the switch is turned off to cut off the driving current from each of the power amplifying circuits to the speaker so that the driving of the speaker is halted.

8. The speaker protection circuit according to claim 5,
wherein a register that operates on a predetermined reference clock is provided within an output circuit of the first voltage comparator, and
an output voltage of the first voltage comparator is stored once in the register based on the reference clock and then is outputted from the register so that a change in the output voltage of the voltage comparator that occurs in a time period shorter than a cycle of the reference clock is not transmitted to a succeeding stage.

9. A speaker protection circuit for use in a BTL amplifying device that drives a speaker using two power amplifying circuits to which two signals whose phases are inverted from each other are inputted, respectively,
each of the two power amplifying circuits comprising: a muting circuit that halts an amplifying operation of the each of the two power amplifying circuits; and a mute terminal for allowing the muting circuit to operate,
the speaker protection circuit comprising a first voltage comparator that compares a voltage of a reference bias terminal of an amplifying circuit constituting the BTL amplifying device with a preset threshold voltage, an output of the first voltage comparator being connected to the mute terminal,
wherein when the voltage of the reference bias terminal is lower than the threshold voltage, based on an output level of the first voltage comparator, the amplifying operation of at least one of the two power amplifying circuits is halted by the corresponding muting circuit so that driving of the speaker is halted.

10. The speaker protection circuit according to claim 9, further comprising a second voltage comparator that compares the voltage of the reference bias terminal with a second threshold voltage higher than the threshold voltage,
wherein when the voltage of the reference bias terminal is higher than the second threshold voltage, based on an output level of the second voltage comparator, the amplifying operation of at least one of the two power amplifying circuits is halted by the muting circuit so that the driving of the speaker is halted.

11. The speaker protection circuit according to claim 9, further comprising:
a low-pass filter that smooths a signal inputted from an input terminal and outputs a DC voltage;
a third voltage comparator that compares an output voltage of the low-pass filter with a third threshold voltage; and
a fourth voltage comparator that compares the output voltage of the low-pass filter with a fourth threshold voltage higher than the third threshold voltage,
wherein when the output voltage of the low-pass filter is lower than the third threshold voltage or higher than the fourth threshold voltage, the amplifying operation of at least one of the two power amplifying circuits is halted by the muting circuit so that the driving of the speaker is halted.

12. The speaker protection circuit according to claim 9,
wherein a register that operates on a predetermined reference clock is provided within an output circuit of the first voltage comparator, and
an output voltage of the first voltage comparator is stored once in the register base on the reference clock and then is outputted from the register so that a change in the output voltage of the voltage comparator that occurs in a time period shorter than a cycle of the reference clock is not transmitted to a succeeding stage.
